(19) United States
(12) Patent Application Publication
(10) Pub. No.: US 2024/0045331 A1
(43) Pub. Date: Feb. 8, 2024

(54) PHOTOSENSITIVE RESIN COMPOSITION, BOARD WITH CONDUCTIVE PATTERN, ANTENNA ELEMENT, PRODUCTION METHOD FOR IMAGE DISPLAY DEVICE, AND PRODUCTION METHOD FOR TOUCH PANEL

(71) Applicant: TORAY INDUSTRIES, INC., Tokyo (JP)

(72) Inventors: Toshiyasu HIBINO, Otsu-shi (JP); Hiroko MITSUI, Otsu-shi (JP)

(73) Assignee: TORAY INDUSTRIES, INC., Tokyo (JP)

(21) Appl. No.: 18/021,707

(22) PCT Filed: Jul. 13, 2021
(86) PCT No.: PCT/JP2021/026235

§ 371 Date: Feb. 16, 2023

(30) Foreign Application Priority Data
Sep. 28, 2020 (JP) 2020-161697

(51) Int. Cl. G03F 7/039; G03F 7/004; G03F 7/038; H01Q 1/38

(52) U.S. Cl. CPC G03F 7/039; G03F 7/0047; G03F 7/0042; G03F 7/038; H01Q 1/38; G06F 3/041

(57) ABSTRACT

Provided is a photosensitive resin composition that makes it possible to suppress residue on a board. The photosensitive resin composition contains conductive particles (A) that have a coating layer that includes carbon, an alkali-soluble resin (B), a photoinitiator (C), and a solvent (D). The solvent (D) contains an amide solvent (dl).

### TECHNICAL FIELD

The present invention relates to a photosensitive resin composition, a substrate having a electrically conductive pattern, an antenna element, a production method for an image display device, and a production method for a touch panel.

### BACKGROUND ART

In recent years, advanced studies have been performed in an effort to develop various displays with increased visibility including TV sets, mobile devices, car navigation systems, and digital signage displays. In particular, for displays equipped with touch panels with electrically conductive patterns intended for use in car navigation systems etc., technological development studies are now being actively carried out to provide fine electronic wiring that is required for suppressing the reflection of external light.

A method commonly adopted to manufacture an electrically conductive pattern for such wiring is to form a pattern on a substrate from a resin composition containing electrically conductivity particles and a binder resin and then heating it to bring the electrically conductive particles into contact with each other to produce an electrically conductive pattern (Patent document 1). Methods that are useful to form a pattern on a substrate include, for example, the screen printing method, ink jet printing method, and photolithography method. Of these, the screen printing method and ink jet printing method cannot serve effectively to form a fine pattern, whereas the photolithography method is suited for forming a fine pattern.

Here, for forming electronic wiring with increased electrically conductivity, there is a known technique that adopts electrically conductive particles having a sufficiently small particle diameter in order to reduce the surface energy of the particles so that the fusion bonding among the electrically conductive particles is promoted. An example of such a resin composition containing electrically conductive particles with a sufficiently small particle diameter is a resin composition prepared by using surface-coated fine silver particles (Patent document 2). The use of surface-coated fine silver particles serves for appropriate control of the surface energy of the fine silver particles.

### PRIOR ART DOCUMENTS

### Patent Documents

Patent document 1: Japanese Unexamined Patent Publication (Kokai) No. 2000-199954

Patent document 2: Japanese Unexamined Patent Publication (Kokai) No. 2013-196997

### SUMMARY OF INVENTION

### Problems to be Solved by the Invention

However, the use of a photosensitive resin composition containing surface-coated fine silver particles often causes residues on a substrate, particularly on a film containing an organic component, during the formation of a pattern. Accordingly, a pattern formed from such a photosensitive resin composition has the problem of leading to a display that is low in visibility due to deterioration caused by the reflection of external light.

The present invention was made in view of these defects in the conventional techniques and aims to provide a photosensitive resin composition that serves to realize a decrease of residues on the substrate.

### Means of Solving the Problems

As a result of intensive studies, the present inventors found that the use of a photosensitive resin composition including a nitrogen-containing compound works very effectively in solving the problem.

Specifically, the present invention relates to a photosensitive resin composition including: electrically conductive particles (A) having carbon-containing coat layers, an alkali-soluble resin (B), a photosensitizing agent (C), and a nitrogen-containing compound (d) having a boiling point of 100° C. to 250° C. under atmospheric pressure.

### Advantageous Effects of the Invention

The use of the photosensitive resin composition according to the present invention makes it possible to suppress residue formation and serves for forming an electrically conductive pattern having a good appearance.

### DESCRIPTION OF PREFERRED EMBODIMENTS

The photosensitive resin composition according to the present invention is characterized by including electrically conductive particles (A) having carbon-containing coat layers, an alkali-soluble resin (B), a photosensitizing agent (C), and a nitrogen-containing compound (d) having a boiling point of 100° C. to 250° C. under atmospheric pressure.

(Electrically Conductive Particles (A) Having Carbon-Containing Coat Layers)

The photosensitive resin composition according to the present invention includes electrically conductive particles (A) having carbon-containing coat layers (hereinafter occasionally referred to simply as electrically conductive particles (A)). The electrically conductive particles (A) are in the form of particles having surfaces coated with, for example, a carbon compound. Examples of the carbon compound include aromatic hydrocarbons, aliphatic hydrocarbons, and oxides, nitrides, sulfides, phosphides, etc. thereof. In particular, the use of an aromatic hydrocarbon, an aliphatic hydrocarbon, or an oxide thereof is preferable from the viewpoint of serving to suppress fusion bonding among the electrically conductive particles (A). If the electrically conductive particles (A) are included, they act to allow the undermentioned cured film to become electrically conductive. In addition, the surfaces of the electrically conductive particles are covered by carbon-containing coat layers and they serve to suppress the fusion bonding among electrically conductive particles at low temperatures and prevent the resolution from being decreased by bulky particles.

Such electrically conductive particles may be fine particles of metal such as, for example, gold (Au), silver (Ag), copper (Cu), nickel (Ni), tin (Sn), bismuth (Bi), lead (Pb), zinc (Zn), palladium (Pd), platinum (Pt), aluminum (Al), tungsten (W), and molybdenum (Mo). In particular, they are preferably fine metal particles containing at least one element selected from the group consisting of gold, silver, copper, nickel, tin, bismuth, lead, zinc, palladium, platinum, and aluminum, and it is more preferable for them to be fine particles of silver from the viewpoint of improving the electrical conductivity.

A typical method for coating the surfaces of electrically conductive particles with carbon-containing coat layers is to bring a reactive gas into contact with the electrically conductive particles by the thermal plasma technique (Japanese Unexamined Patent Publication (Kokai) No. 2007-138287), It is preferable for the surface of each of the electrically conductive particles (A) to be coated completely, but there may be some particles having surfaces that are coated incompletely as long as the objects of the present invention are met.

The coat layers preferably have an average thickness of 0.1 to 10 nm. If it is in this range, it serves to suppress the fusion bonding among the electrically conductive particles to ensure improved fine pattern processability, and in addition, their electrical conductivity will be further increased when they are heat-treated at a temperature of 300° C. or less.

To determine the average thickness of the coat layers, the mass decrease in the electrically conductive particles (A) is measured by a thermobalance, and on the assumption that the value is attributed entirely to the combustion of carbon, the average thickness of the coat layers is calculated from the particle diameter assuming that the carbon density is 2.0. Electrically conductive particles having a known particle diameter (Dp) are coated with carbon to an average thickness of A (μm), and the number of electrically conductive particles coated with carbon is hereinafter referred to as n. In the thermobalance measurement, the first measured mass value is referred to as W₁ (g) and the mass value measured after complete combustion of carbon is referred to as W₂ (g), and if Dp and W₂ are determined, n can be calculated by the equation given below wherein p is the density of the electrically conductive particles.

W₂=π/6×Dp³ρ×n

Then, the average thickness of the coat layers, which is referred to as A, can be calculated by the equation given below.

W₁−={4/3×π(Dp/2+A)³−π/6×Dp³}×2.0×n

It is preferable for the electrically conductive particles (A) to have an average primary particle diameter of 1 to 700 nm. If the average primary particle diameter is 1 nm or more, it allows the particles to have a smaller specific surface area and stable dispersion can be achieved even when the quantity of the dispersing agent used is small. If the average primary particle diameter is 700 nm or less, furthermore, it serves for the formation of a fine pattern. Here, the average primary particle diameter of the electrically conductive particles (A) is determined by measuring the particle diameters of randomly selected 100 primary particles by scanning electron microscopy and averaging the measurements. To determine the particle diameter of each primary particle, the maximum diameter and the minimum diameter of the primary particle is measured and their average is calculated.

In the photosensitive resin composition according to the present invention, it is preferable that the electrically conductive particles (A) account for 65 to 95 mass % of the total solid quantity which accounts for 100 mass %. If their content is 65 mass % or more, the residual organic components will be unable to prevent the contact among the electrically conductive particles (A), leading to a higher electrical conductivity. The content is preferably 75 mass % or more. On the other hand, if their content is 95 mass % or less, the residual organic components will work to stabilize the dispersibility of the electrically conductive particles (A) in the photosensitive resin composition to ensure the formation of a fine pattern, thereby leading to a further decrease in the amount of residue on the substrate. The content is preferably 85 mass % or less. Here, the total solid quantity means the quantity of all components except the solvent contained in the photosensitive resin composition.

The proportion accounted for by the electrically conductive particles (A) in the total solid quantity can be determined based on quantitative analysis of all components in the photosensitive resin composition. It is noted that the proportions of other components described later can also be calculated by the same method.

The method to use for the analysis of all components in the photosensitive resin composition is as described below.
(i) The photosensitive resin composition is diluted with an organic solvent and its features are investigated by ¹H-NMR spectroscopy, GC analysis, and GC/MS analysis.
(ii) The photosensitive resin composition is subjected to extraction with an organic solvent, followed by centrifugal separation to separate soluble components and insoluble components.
(iii) The insoluble components obtained above are subjected to extraction with a high polarity organic solvent, followed by centrifugal separation to further separate soluble components and insoluble components.
(iv) The liquid mixtures of soluble components obtained in (ii) and (iii) above are examined by IR spectroscopy, ¹H-NMR spectroscopy, and GC/MS analysis. Furthermore, the liquid mixture is subjected to fractionation by GPC. The resulting fractions are examined by IR spectroscopy and ¹H-NMR spectroscopy. The fractions are also examined by GC analysis, GC/MS analysis, pyrolysis GC/MS analysis, and MALDI/MS analysis as required.
(v) The insoluble components obtained in (iii) above are examined by IR spectroscopy or TOF/SIMS spectrometry. If an organic substance is found to exist, additional examination is performed by pyrolysis GC/MS or TPD/MS analysis.
(vi) The content of each component contained in the photosensitive resin composition can be determined by overall study of the measuring results obtained in the above paragraphs (i), (iv), and (v). It is noted that it is preferable to use chloroform, methanol, or the like as the high polarity organic solvent in (iii).

(Alkali-Soluble Resin (B))

The photosensitive resin composition according to the present invention contains an alkali-soluble resin (B). There are no specific limitations on the alkali-soluble resin (B), and a suitable resin is selected appropriately to suite the viscosity etc. of the photosensitive resin composition. Useful resins for the alkali soluble resin (B) include, for example, cardo resin, polyimide resin, polyester resin, acrylic resin, polyhydroxystyrene based resin, and novolac resin, of which acrylic resin, cardo resin, and polyimide resin are preferable from the viewpoint of easy composition design and acrylic resin is particularly preferable from the viewpoint of easy availability. Here, an acrylic resin means a resin produced by copolymerizing a resin component with at least a (meth)acrylic monomer. Examples of the (meth)acrylic monomer referred to above include methyl (meth)acrylate, ethyl (meth)acrylate, n-propyl (meth)acrylate, n-butyl (meth)acrylate, tert-butyl (meth)acrylate, tert-butoxycarbonyl (meth)acrylate, benzyl (meth)acrylate, methyladamantyl (meth)acrylate, cyclohexyl (meth)acrylate, tetrahydropyranyl (meth)acrylate, dicyclopentanyl (meth)acrylate, dicyclopentenyl (meth)acrylate, glycidyl (meth)acrylate, 2-hydroxyethyl (meth)acrylate, isobonyl (meth)acrylate, and phenyl (meth)acrylate.

Useful copolymerization components other than the (meth)acrylic monomers include compounds having carbon-carbon double bonds. Examples of such compounds include aromatic vinyl compounds such as styrene, p-methyl styrene, o-methyl styrene, m-methyl styrene, α-methyl styrene, and p-hydroxyl styrene; amide based unsaturated compounds such as (meth)acrylamide, N-methylol (meth)acrylamide, and N-vinyl pyrrolidone; and others such as (meth)acrylonitrile, allyl alcohol, vinyl acetate, cyclohexylvinyl ether, n-propylvinyl ether, i-propylvinyl ether, n-butylvinyl ether, i-butylvinyl ether, 2-hydroxyethylvinyl ether, and 4-hydroxybutylvinyl ether.

It is preferable for the alkali-soluble resin (B) to have a heat-decomposable group. A heat-decomposable group means an organic group that undergoes thermo-oxidative degradation and elimination when heated. If such a heat-decomposable group is contained, the heat-decomposable group will easily undergo thermo-oxidative degradation and will be eliminated when, for example, it is heated in an acidic atmosphere at 100° C. to 300° C. to cause shrinkage of the cured film, thereby leading to an increase in the content of the electrically conductive particles in the cured film and an increase in electrical conductivity. As a result of this, it will be easier to achieve an intended electrical conductivity at a specific resistance of 2 to 1,000 pf-cm. In this case, a more noticeable effect can be realized by a combined use with a photoacid generating agent and/or a thermal acid generating agent as described later.

The heat decomposable group is preferably an organic group having 4 to 15 carbon atoms. If the heat decomposable group has 4 or more carbon atoms, it will be vaporized at a low temperature after being eliminated so that large bubbles that work to prevent the contact among electrically conductive particles will not be generated in the cured film, leading to a further improvement in electrical conductivity. It is preferable for the heat decomposable group to have 6 or more carbon atoms. On the other hand, if the heat decomposable group has 15 or less carbon atoms, dissociative groups that work to prevent the contact among electrically conductive particles will not be left in the cured film after the group is eliminated, leading to a further improvement in electrical conductivity. Furthermore, if bubbles are generated in the cured film, they will be dissipated easily by heating.

Examples of such a heat decomposable group include tert-butyl group, tert-butoxycarbonyl group, benzyl group, methyladamantyl group, and tetrahydropyranyl group.

The alkali-soluble resin (B) is preferably a resin that is copolymerized with a compound having a heat decomposable group in a proportion of 20 to 80 mol %. In particular, in the case where the alkali soluble resin (B) is an acrylic resin, it is preferable that an (meth)acrylate having a heat decomposable group be contained as a monomer component and account for 20 to 80 mol % in the acrylic resin.

The alkali-soluble resin (B) has an alkali-soluble group. Examples of the alkali soluble group include carboxyl groups, hydroxyl groups, sulfo groups, phosphate groups, and anhydride groups, of which carboxyl groups and hydroxyl groups are particularly preferable from the viewpoint of reactivity and versatility. By adjusting the ratio between the carboxyl groups and hydroxyl groups contained, it is possible to control the alkali-solubility as desired.

As the alkali soluble resin (B) to use for the present invention, it is preferable to adopt an acrylic resin containing a carboxyl group and/or a hydroxyl group in order to ensure easy composition design. Examples of such a compound containing a carboxyl group to use as the copolymerization component serving to develop alkali-solubility include, for example, (meth)acrylic acids, itaconic acid, crotonic acid, maleic acid, fumaric acid, and anhydrides thereof. Furthermore, an epoxy compound may be added to the carboxyl group so that the carboxyl group is esterified to form a hydroxyl group.

The alkali-soluble resin (B) preferably has a carboxylic acid equivalent weight of 50 to 1,000 g/mol. The carboxylic acid equivalent weight can be calculated from measurement of the acid value. In addition, it is preferable for the alkali-soluble resin (B) to have a double bond equivalent weight of 150 to 10,000 g/mol because it serves to ensure both a high hardness and a high crack resistance. The double bond equivalent weight can be calculated from measurement of the iodine value.

It is preferable for the alkali-soluble resin (B) to have a polystyrene-based weight average molecular weight (Mw) in the range of 1,000 to 100,000 as determined by gel permeation chromatography (GPC). If it has a weight average molecular weight (Mw) in the above range, it will have good coating characteristics and also have a high solubility in the developer used for pattern formation.

To ensure a high curing reaction rate of the photosensitive resin composition according to the present invention during the light exposure step, it is preferable for the alkali-soluble resin (B) to be a (meth)acrylic copolymer having a carbon-carbon double bond in a side chain or at a molecular end. Examples of a functional group having a carbon-carbon double bond include vinyl groups, allyl groups, and (meth)acrylic groups. To add such a functional group to a (meth)acrylic copolymer, a good method is to add a compound having both a glycidyl group or an isocyanate group and a carbon-carbon double bond, or a (meth)acrylic acid chloride, or an allyl chloride to the mercapto group, amino group, hydroxyl group, or carboxyl group in the (meth)acrylic copolymer through an addition reaction.

Examples of a compound having both a glycidyl group and a carbon-carbon double bond include glycidyl (meth)acrylate, allyl glycidyl ether, glycidyl ethyl acrylate, crotonyl glycidyl ether, glycidyl crotonate, and glycidyl isocrotonate. Examples of a compound having both an isocyanate group and a carbon-carbon double bond include (meth)acryloyl isocyanate and (meth)acryloyloxyethyl isocyanate.

For the photosensitive resin composition according to the present invention, it is preferable for the alkali-soluble resin (B) to account for 1 to 30 mass % of the total solid content which accounts for 100 mass %. If its content is 1 mass % or more, it allows the photosensitive resin composition to be adjusted to a viscosity suitable for coating, whereas if it is 30 mass % or less, it ensures an improved electrical conductivity.

(Photosensitizing Agent (C))

The photosensitive resin composition according to the present invention contains a photosensitizing agent (C), and this allows the photosensitive resin composition to have positive or negative photosensitivity and to be processed into a pattern by the photolithography technique.

It is preferable for the photosensitizing agent (C) to be a photo-initiator, a photo-acid generator, or a photo-base generator. Examples of the photo-initiator include acetophenone based compounds, benzophenone based compounds, benzoin ether based compounds, α-aminoalkyl phenon based compounds, thioxanthone based compounds, organic peroxides, imidazole based compounds, titanocene based compounds, triazine based compounds, acylphosphine oxide compounds, quinone compounds, and oxime ester based compounds, of which oxime ester based compounds are preferable because they can work to develop a high sensitivity even when added in small amounts, wherein oxime ester based compounds having carbazole backbones are more preferable.

Specific examples of an oxime ester based compound having a carbazole backbone include 3-cyclopentyl ethanone, 1-[9-ethyl-6-(2-methylbenzoyl)-9H-carbazole-3-yl]-, 1-(0-acetyl oxime), ethanone, 1-[9-ethyl-6-(2-methylbenzoyl)-9H-carbazole-3-yl]-, 1-(0-acetyl oxime).

Besides, specific examples of an oxime ester based compound not having a carbazole backbone include 1,2-propanedione-3-cyclopentane, 1-[4-(phenylthio)-2-(O-benzoyloxime], and 1,2-octanedione, 1-[4-(phenylthio)-2-(O-benzoyloxime)].

In the photosensitive resin composition according to the present invention, the photo-initiator preferably accounts for 1 to 50 parts by mass relative to 100 parts by mass of the alkali-soluble resin (B).

Examples of the photo-acid generator include quinonediazide compounds, sulfonium salts, phosphonium salts, diazonium salts, and iodonium salts, of which quinonediazide compounds are more preferable. The quinonediazide compounds include those having 5-naphthoquinonediazide sulfonyl groups and those having 4-naphthoquinonediazide sulfonyl groups, and both can be used preferably. Such naphthoquinonediazide sulfonates include polyhydroxy compounds bonded to sulfonic acid of quinonediazide through ester linkage, polyamino compounds bonded to sulfonic acid of quinonediazide through sulfonamide linkage, and polyhydroxypolyamino compounds bonded to sulfonic acid of quinonediazide through ester linkage and/or sulfonamide linkage.

Examples of the photo-base generator include amide compounds and ammonium salts.

Such amide compounds include, for example, 2-nitrophenylmethyl-4-methacryloyloxy piperidine-1-carboxylate, 9-anthrylmethyl-N,N-dimethyl carbamate, 1-(anthraquinone-2-yl) ethylimidazole carboxylate, and (E)-1-[3-(2-hydroxyphenyl)-2-propenoyl] piperidine.

Such ammonium salts include, for example, 1,2-diisopropyl-3-(bisdimethylamino)methylene) guanidium 2-(3-benzoylphenyl)propionate, (Z)-{[bis(dimethylarnino)methylidene] amino}-N-cyclohexylamino)methaniumtetrakis(3-fluorophenyl) borate, and 1,2-dicyclohexyl-4,4,5,5-tetramethylbiguanidium n-butyltriphenyl borate.

(Nitrogen-Containing Compound (d))

The photosensitive resin composition according to the present invention contains a nitrogen-containing compound (d) that has a boiling point of 100° C. to 250° C. under atmospheric pressure. Nitrogen atoms in the nitrogen-containing compound (d) interact with carbon atoms in the coat layer on the electrically conductive particles to enhance their dispersibility, and accordingly, it serves to prevent development residues from being formed from coagulation of the electrically conductive particles. In addition, it has a boiling point of 100° C. to 250° C. under atmospheric pressure, and accordingly, the nitrogen-containing compound (d) existing in the coat film can be removed easy out of the cured film by heating and drying, thus serving to produce a cured film having an increased electrical conductivity. The nitrogen-containing compound (d) gets out of the coat film as it volatilizes during heating and drying of the coat film, which originates from a photosensitive resin composition. Therefore, it is preferably a compound that interacts moderately with the electrically conductive particles, and an amide compound is used preferably. Furthermore, in the case where the nitrogen-containing compound (d) is liquid at room temperature under atmospheric pressure, it can also act as the solvent (D) that will be described later.

Examples of the nitrogen-containing compound (d), which has a boiling point of 100° C. to 250° C. under atmospheric pressure, include dimethylcyanamide (164° C.), N,N-dimethylformamide (153° C.), (dimethylamino)acetonitrile (138° C.), 1-(2-hydroxyethyl)ethylene imine (156° C.), 2-(dimethylamino)ethanol (134° C.), 3-dimethylaminopropionitrile (171° C.), diethylcyanamide (188° C.), 1-ethylpyrrolidine (105° C.), 1-methylpiperidine (107° C.), 3-hydroxy-1-methylpyrrolidine (182° C.), N,N-diethylformamide (177° C.), 4-methylmorpholine (116° C.), 3-(dimethylamino)-1-propanol (164° C.), 1-dimethylamino-2-propanol (125° C.), diethylaminoacetonitrile (170° C.), N,N-diethylallylamine (110° C.), 1-ethylpiperidine (131° C.), N,N′-dimethylpiperazine (133° C.), 4-ethylmorpholine (139° C.), tetramethylurea (177° C.), N,N,N′,N′,tetramethylethylene diamine (122° C.), N,N-dimethylglycine methyl (135° C.), 2-diethylaminoethanol (162° C.), N,N-dimethylaniline (194° C.), N,N-dimethylcyclohexylamine (160° C.), N,N-diisopropylformamide (190° C.), N,N-diisopropylethylamine (127° C.), N,N-dipropylethylamine (132° C.), N,N,N′,N′-tetramethyl-1,3-diaminopropane (145° C.), 2-(dimethylamino)ethylacetate (152° C.), 1-diethylamino-2-propanol (159° C.), 3-diethylamino-1-propanol (189° C.), N-benzyldimethylamine (180° C.), 2-dimethylaminotoluene (186° C.), triallylamine (156° C.), 2-(dimethylamino)ethylacrylate (161° C.), tripropylamine (156° C.), 1,3-bis(dimethylamino)butane (169° C.), 2-(diisopropylamino)ethanol (191° C.), N,N-diethylcyclohexylamine (193° C.), triisobutylamine (183° C.), 1-methyl-2-pyrrolidone (202° C.), N-methylsuccinimido (235° C.), 1-ethyl-2-pyrrolidone (218° C.), 3-(dimethylamino)-1,2-propanediol (217° C.), N-methyldiethanol amine (245° C.), 1-acetylpyrrolidone (225° C.), 1-formpiperidine (222° C.), 4-formylmorpholine (237° C.), N-ethylmaleimide (210° C.), 1-acetyl-2-pyrrolidone (231° C.), 4-(2-hydroxyethyl) morpholine (222° C.), N-methylformanilide (243° C.), 4-dimethylaminotoluene (211° C.), 4-(3-hydroxylpropyl)morpholine (241° C.) N-(2-hydroxypropyl)morpholine (218° C.), 3-(diethylamino)-1,2-propanediol (233° C.), N,N-diethyl aniline (216° C.), N,N-dibutyl formamide (243° C.), N,N-diethyl-p-toluidine (230° C.), N,N-diethyl-o-toluidine (210° C.), N,N,2,4,6-pentamethylaniline (215° C.), 1,1,3,3-tetraethylurea (214° C.), acrylamide (106° C.), 2-methyl-2-oxazoline (110° C.), 2-ethyl-2-oxazoline (128° C.), 2-propyl-2-oxazoline (147° C.), N,N-dimethylacetamide (165° C.), N,N-dimethylpropion amide (176° C.), trifluoroacetamide (163° C.), 2,2,4-trimethyl-2-oxazoline (112° C.), 2-isopropyl-2-oxazoline (138° C.), N,N-diethylacetamide (185° C.), N,N-dimethylisobutyl amide (179° C.), N-methyltrifluoroacetamide (160° C.), N,N-diethylpropion amide (191° C.), 2,2,2-trifluoro-N,N-dimethylacetamide (136° C.), N-methyl-N-trimethylsilylacetamide (154° C.), N-tert-butylmaleimide (190° C.), N,N-diethyl-2,2,2-trifluoroacetamide (160° C.), N-methyl-N-trimethylsilyltrifluoroacetamide (132° C.), N-methylformamide (183° C.), nitromethane (101° C.), and methylcarbamate (177° C.).

(Solvent [D])

The photosensitive resin composition according to the present invention preferably contains a solvent (D). The solvent (D) is used with the aim of achieving uniform mixing of all components contained in the photosensitive resin composition according to the present invention in order to form a uniform coat film. As the solvent (D), general purpose solvents including glycol based solvents, glycol ester based solvents, alcohol solvents, ketone based solvents, lactone based solvents, amine based solvents, sulfone based solvents, ester based solvents, and amide based solvents are available and a plurality thereof may be used in combination.

In the case where the nitrogen-containing compound (d), which has a boiling point of 100° C. to 250° C. under atmospheric pressure and is contained in the photosensitive resin composition according to the present invention, is liquid at room temperature under atmospheric pressure, it can also work as the solvent (D). In that case, it is preferable to adopt an amide based solvent (d1) because it vaporizes in the drying step to ensure easy removal.

Substances that can be used as the amide based solvent (d1) include N,N-dimethylformamide, N,N-diethylformamide, N,N-diisopropylformamide, N,N-dibutylformamide, acrylamide, N,N-dimethylacetamide, N,N-dimethylpropionamide, trifluoroacetamide, N,N-diethylacetamide, N,N-dimethylisobutylamide, N-methyltrifluoroacetamide, N,N-diethylpropionamide, 2,2,2-trifluoro-N,N-dimethylacetamide, N-methyl-N-trimethylsilylacetamide, N,N-diethyl-2,2,2-trifluoroacetamide, N-methyl-N-trimethylsilyltrifluoroacetamide, and N-methylfonrmamide. Among others, it is preferable for the amide based solvent (d1) to be a compound as represented by the general formula (1) given below from the viewpoint of suppressing more strongly the formation of residues on an organic film and ensuring a higher pattern processability and electrical conductivity.

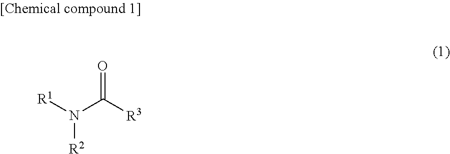

In the general formula (1) given above, R¹ and R² are each independently a hydrogen atom or a linear alkyl group having 1 to 3 carbon atoms. If R¹ and R² are each a linear alkyl group containing 1 to 3 carbon atoms, it serves to reduce their steric hindrance and ensure easy interaction with electrically conductive particles.

In the general formula (1) given above, R³ is an organic group having 1 to 4 carbon atoms and preferably an organic group having 2 to 4 carbon atoms. The organic group may be, for example, an aliphatic hydrocarbon group. The aliphatic hydrocarbon group may be linear or branched or may be partly or entirely cyclic. Furthermore, it may be a saturated hydrocarbon group or an unsaturated hydrocarbon group, and at least part of the hydrogen atoms may be substituted by substituent groups. Useful groups that can serve as R³ include, for example, ethyl group, n-propyl group, isopropyl group, n-butyl group, isobutyl group, 2-hydroxyethyl group, 2-methoxyethyl group, 2-hydroxypropyl group, 2-methoxypropyl group, 3-hydroxypropyl group, 3-methoxypropyl group, 2-hydroxybutyl group, 3-hydroxybutyl group, and 4-hydroxybutyl group.

Here, in the case where an R has a substituent group, the number of carbon atoms referred to above includes the number of carbon atoms existing in the substituent group.

In the above general formula, the total number of carbon atoms existing in R¹, R², and R³ is preferably in the range of 4 to 8. If it is in this range, it ensures appropriate interaction with electrically conductive particles.

The nitrogen-containing compound (d) has a boiling point of 100° C. to 250° C. under atmospheric pressure. As it has a boiling point of 100° C. or more, it serves to prevent uneven coating in the coating step to ensure a high film uniformity. On the other hand, as it has a boiling point of 250° C. or less, the solvent can volatilize easily in the film curing step to ensure an increased electrical conductivity. The boiling point of the nitrogen-containing compound (d) is more preferably in the range between a lower limit of 150° C. or more and an upper limit of 220° C. or less. If it is in this range, it serves to improve both film uniformity and electrical conductivity.

The solvent (D) contained in the photosensitive resin composition may include a solvent other than the amide based solvent (d1). Examples of such other solvents include propylene glycol monomethyl ether, propylene glycol monobutyl ether, diacetone alcohol, propylene glycol monoethyl ether acetate, ethyl acetoacetate, cyclopentanone, cyclohexanone, γ-butyrolactone, ethylene glycol monobutyl ether acetate, diethylene glycol monoethyl ether acetate, diethylene glycol monobutyl ether acetate, diethylene glycol dimethyl ether, diethylene glycol diethyl ether, diethylene glycol methylethyl ether, dipropylene glycol methyl ether acetate, dipropylene glycol dimethyl ether, propylene glycol diacetate, 1,3-butylene glycol diacetate, cyclohexanol acetate, dimethyl sulfoxide, methyl ethyl ketone, isobutyl acetate, butyl acetate, propyl acetate, isopropyl acetate, and acetylacetone.

In the aforementioned solvent (D) contained in the photosensitive resin composition, the amide based solvent (d1) preferably accounts for 5 to 65 mass %. When the content is 5 mass % or more, it can act more strongly to reduce residues. On the other hand, when the content is 65 mass % or less, the amount of the solvent in the photosensitive resin composition decreases to realize an increase in the drying speed, thereby reducing uneven drying.

(Dispersing Agent (E))

It is preferable for the photosensitive resin composition according to the present invention to contain a dispersing agent (E). The inclusion of the dispersing agent (E) allows the electrically conductive particles (A) to stay stably in the photosensitive resin composition.

Preferred materials for the dispersing agent (E) include a dispersing agent (E1) that has a tertiary amine and/or quaternary ammonium salt structure, a silver resinate compound (E2), which will be described later, and an aliphatic carboxylic acid (E3).

Examples of an amine based dispersing agent (E) include DISPERBYK (registered trademark) 142, 145, 161, 167, 180, 2001, 2008, 2022, 2150, 6919, and 21116 (all manufactured by BYK-Chemie Japan). In particular, it is preferable to use a dispersing agent (E1) that has a tertiary amine and/or quaternary ammonium salt structure.

To ensure increased dispersibility, furthermore, it is preferable for the dispersing agent (E) to have an acrylic block copolymer structure. Examples of an amine based dispersing agent (E) that has an acrylic block copolymer structure include DISPERBYK (registered trademark) 2001, 2008, 2022, 2150, 6919, and 21116.

In the photosensitive resin composition according to the present invention, it is preferable for the dispersing agent (E) to account for 1 to 10 parts by mass relative to the total, i.e. 100 parts by mass, of the electrically conductive particles (A) and other particles that will be described later existing in the photosensitive resin composition. When the content of the component (E) is in this range, the electrically conductive particles (A) will be dispersed favorably in the photosensitive resin composition to ensure fine pattern processing. In addition, this allows the electrically conductive particles (A) to come into contact easily with each other to undergo fusion bonding in the photosensitive resin composition, thereby ensuring a higher electrical conductivity.

(Silver Resinate Compound (E2))

It is preferable for the photosensitive resin composition according to the present invention to contain a silver resinate compound (E2). It is preferable for the resinate compound (E2) to be a salt of carboxylic acid, which is an organic acid, and silver, namely, a silver carboxylate. If a silver resinate compound (E2) is contained in the photosensitive resin composition, the organic acid portion is decomposed in the film curing step to promote the fusion bonding of the electrically conductive particles (A), thereby enhancing the electrical conductivity. Furthermore, the silver portions tend to be adsorbed on the surfaces of the electrically conductive particles (A) to act as a dispersing agent for the electrically conductive particles (A).

Such silver carboxylates include, for example, silver acetate, silver propionate, silver butyrate, silver isobutyrate, silver lactate, silver pyruvate, silver glyoxylate, silver malonate, silver laurate, silver 2-ethylhexanoate, silver neodecanoate, silver stearate, silver palmitate, silver behenate, silver oleate, silver linoleate, silver acetylacetonate, silver acetonedicarboxylate, silver isobutyrylacetate, silver benzoylacetate, silver acetoacetate, silver propionylacetate, silver α-methylacetoacetate, silver α-ethylacetoacetate, silver pivaloylacetate, silver benzoate, and silver picrate.

In regard to the proportion of the silver resinate compound (E2) to the electrically conductive particles (A), it preferably accounts for 0.1 to 100 parts by weight relative to 100 parts by weight of the electrically conductive particles (A). When it accounts for 0.1 part by weight or more, it will be possible to sufficiently enhance the effect of the conductivity under low temperature curing conditions. It more preferably accounts for 0.5 to 90 parts by weight and still more preferably 1 to 50 parts by weight.

(Aliphatic Carboxylic Acid (E3))

It is preferable for the photosensitive resin composition according to the present invention to contain an aliphatic carboxylic acid (E3). By interacting with the surfaces of the electrically conductive particles (A), the aliphatic carboxylic acid (E3) can act as a dispersing agent for the electrically conductive particles (A). If the aliphatic carboxylic acid (E3) is used as a dispersing agent, the alkali solubility of the electrically conductive particles (A) improves, thereby ensuring the formation of a pattern with a higher resolution, a decrease of development residues, their elimination as a result of heat decomposition and volatilization in the curing step, and enhancement of the fusion bonding of the electrically conductive particles (A). It is preferable for the aliphatic carboxylic acid (E3) to have 1 to 20 carbon atoms, more preferably 4 to 10 carbon atoms. If the number is in this range, it will be easily eliminated in the curing step so that a cured film with a high electrical conductivity will be formed from the photosensitive resin composition according to the present invention. It is preferable for the aliphatic carboxylic acid (E3) to have a branched hydrocarbon chain structure, and it is more preferable that in the branched structure, the carbon atom located at the a position adjacent to the carboxylic acid be a secondary or tertiary carbon atom. If it has a branched structure, a larger steric hindrance occurs to allow the electrically conductive particles (A) to be dispersed more stably, Useful substances for the aliphatic carboxylic acid (E3) include cyclopropanecarboxylic acid, isobutyric acid, 1-methylcyclopropane-1-carboxylic acid, cyclobutanecarboxylic acid, 3-cyclopentene-1-carboxylic acid, 2,2-dimethylbutyric acid, 2-ethylbutyric acid, 2-methylvaleric acid, 3-cyclohexene-1-carboxylic acid, cyclohexanecarboxylic acid, 2,2-dimethyl-4-pentenoic acid, 2,2-dimethylvaleric acid, 6-methyl-3-cyclohexene-1-carboxylic acid, 4-methylcyclohexanecarboxylic acid, cyclopentanecarboxylic acid, 2-methyl-4-pentenoic acid, 2-methyl-3-butenoic acid, DL-2-methylbutyric acid, pivalic acid, 1-methyl-1-cyclohexanecarboxylic acid, 2-methylheptanoic acid, 2-propylvaleric acid, 2-ethylhexanoic acid, 2,2-dimethylhexanoic acid, 4-isopropylcyclohexanecarboxylic acid, and neodecanoic acid. In regard to the proportion of the aliphatic carboxylic acid (E3) to the electrically conductive particles (A), it preferably accounts for 0.1 to 100 parts by weight relative to 100 parts by weight of the electrically conductive particles (A). If it accounts for 0.1 part by weight or more, it allows the electrically conductive particles (A) to undergo fusion bonding easily, thereby ensuring a higher electrical conductivity. It more preferably accounts for 0.5 to 90 parts by weight and still more preferably 1 to 50 parts by weight.

The total proportion of the silver resinate compound (E2) and the aliphatic carboxylic acid (E3) used for the present invention to the electrically conductive particles (A) is preferably such that it accounts for 1 to 10 parts by mass relative to 100 parts by mass of the electrically conductive particles (A). If it is in this range, the aforementioned effect of the silver resinate compound (E2) and the aliphatic carboxylic acid (E3) can be realized without suffering a decrease in the dispersibility of the electrically conductive particles (A) in the photosensitive resin composition.

(Black Compound (F))

It is preferable for the photosensitive resin composition according to the present invention to contain a black compound (F). As such a black compound (F), a pigment or a dye that absorbs visible light can be proposed. If the photosensitive resin composition contains a pigment and/or a dye that absorbs visible light, it serves not only to reduce the visible light reflection by the electrically conductive pattern obtained after the baking step, but also act as an ultraviolet absorber, thereby realizing an improved pattern processability on a substrate on an inorganic film. An inorganic film with a high surface smoothness, such as glass, causes stronger interface reflection than an organic film and such reflected light can have some influence on the pattern. However, an increase in pattern processability is thought to occur as the black compound (F) acts as an ultraviolet absorber to absorb the reflected light moderately.

Examples of the black compound (F) include lactam based pigments, perylene based pigments, phthalocyanine based pigments, isoindoline based pigments, diaminoanthraquinone based pigments, dioxazine based pigments, indanthrone based pigments, carbon black, and inorganic pigments.

More specifically, they include, for example, furnace black materials such as HCF, MCF, LFF, RCF, SAF, ISAF, HAF, XCF, FEF, GPF, and SRF; thermal black materials such as FT and MT; carbon black materials such as channel black and acetylene black; and others such as lactam based pigment products (such as Irgaphor (registered trademark) and Black S0100 CF, manufactured by BASF). Of these, carbon black materials are preferable because they are high in heat resistance, light resistant, and visible light absorptivity, and furnace black and lactam based pigments are more preferable from the viewpoint of electrical conductivity and dispersibility.

Commercial products of carbon black include, for example, MA77, 7, 8, 11, 100, 100 R, 100 S, 230, 220, and 14 (all manufactured by Mitsubishi Chemical Corporation), #52, 47, 45, 45L, 44, 40, 33, 32, 30, 25, 20, 10, 5, 95, 85, and 260 (all manufactured by Mitsubishi Chemical Corporation), Special Black 100, 250, 350, and 550 (all manufactured by Evonik Degussa GmbH), and Printex 95, 90, 55, 45, 40, P, 60, L6, L, 300, 30, ES23, 9, ES22, 35, 25, 200, A, and G. Of these, MA77, 7, 8, 11, 100, 100 R, 10S, 230, 220, and 14, and Special Black 100, 250, 350, and 550 are preferable because they have pH values of 4 or less.

Such a pigment that is contained in the photosensitive resin composition and absorbs visible light preferably accounts for 0.1 to 10 mass % relative to the total solid content in the composition.

Dyes that absorb visible light include ferrocene based dyes, fluorenone based dyes, perylene based dyes, triphenylmethane based dyes, coumarin based dyes, diphenylamine based dyes, quinacridone based dyes, quinophtharone based dyes, phthalocyanine based dyes, and xanthene based dyes. It is preferable to use a black dye that is high in heat resistance, light resistant, and visible light absorptivity, and preferred examples include VALIFAST (registered trademark) Black 1888, VALIFAST (registered trademark) Black 3830, NUBIAN (registered trademark) Black PA-2802, and OIL Black 860.

Such a dye that is contained in the photosensitive resin composition and absorbs visible light preferably accounts for 0.1 to 10 mass % relative to the total solid content in the composition.

(Other Components)

The photosensitive resin composition according to the present invention may include other components with the aim of adjustment of photosensitivity, improvement of reliability of the cured film, etc. Such other components include acrylic monomers, polymerization inhibitor, ultraviolet absorber, metal chelate compounds, thermal acid generating agent, sensitizing agent, contact improving agent, and surface active agent. More specific examples thereof are listed in, for example, International Publication WO 2018/061384.

(Production Method for Electrically Conductive Pattern)

One good production method for an electrically conductive pattern includes a step for forming a dried film of the photosensitive resin composition according to the present invention on a substrate, a step for exposing the dried film to light and developing it to form a pattern on the substrate, and a step for heating the resulting pattern.

First, a dried film of the photosensitive resin composition according to the present invention is formed on a substrate.

Useful substrates include, for example, silicon wafers, ceramic substrates, and organic film substrates. Examples of the ceramic substrates include those of glass such as soda glass, non-alkali glass, borosilicate glass, and quartz glass, and others such as alumina substrate, aluminum nitride substrate, and silicon carbide substrate. Examples of the organic film substrates include acrylic resin substrate, epoxy resin substrate, polyetherimide resin substrate, polyether ketone resin substrate, polysulfone based resin substrate, polyimide film, and polyester film. When producing an electrically conductive pattern using the photosensitive resin composition according to the present invention, the formation of an electrically conductive pattern may be carried out by first forming an organic film on a substrate and then coating it with the photosensitive resin composition with the aim of ensuring a high pattern processability and producing a highly reliable electrically conductive pattern. Furthermore, when producing a stack of a plurality of electrically conductive patterns, the plurality of electrically conductive patterns may be formed with organic films interposed between them. Each organic film is a thin film that is formed by spreading a resin composition containing at least a resin, such as acrylic resin, cardo resin, and epoxy resin, and a solvent and curing it, and its thickness is preferably about 0.5 to 100 μm.

Useful methods for coating a substrate with the photosensitive resin composition include, for example, coating with a spin coater, bar coater, blade coater, roll coater, die coater, calender coater, or meniscus coater, as well as screen printing, spray coating, and dip coating.

Useful drying methods include, for example, hot plate drying, hot air drying (using an oven), drying under reduced pressure, vacuum drying, and infrared ray irradiation.

The drying temperature and time to use may be set appropriately depending on the components of the photosensitive resin composition and the thickness of the coating film to be dried, but it is generally preferable to heat it in the temperature range of 50° C. to 150° C. for 10 seconds to 30 minutes.

In particular, the combined implementation of heating with a hot plate or a hot air drier (oven) and drying under reduced pressure is preferable because it serves to remove the solvent by drying while suppressing the heat-curing of the resin contained in the coating film. The maximum pressure to be reached for the drying under reduced pressure is preferably 10 to 200 Pa and more preferably 30 to 100 Pa.

Then, the dried film is exposed to light and developed to form a pattern on the substrate.

Preferable light sources to use for the light exposure include, for example, the j-line, i-line, h-line, and g-line of a mercury lamp.

Alkaline compounds that can be used in an alkaline developer solution to use for the development step include, for example, inorganic alkali substances including sodium hydroxide, potassium hydroxide, sodium carbonate, potassium carbonate, sodium silicate, sodium metasilicate, and aqueous ammonia; and organic alkali substances including primary amines such as ethyl amine and n-propyl amine, secondary amines such as diethyl amine and di-n-propyl amine, tertiary amines such as triethyl amine and methyldiethyl amine, tetraalkyl ammonium hydroxides such as tetramethyl ammonium hydroxide (TMAH), quaternary ammonium salts such as choline, alcohol amines such as triethanol amine, diethanol amine, monoethanol amine, dimethyl aminoethanol, and diethyl aminoethanol, and cyclic amines such as pyrrole, piperidine, 1,8-diaza-bicyclo[5,4,0]-7-undecene, 1,5-diaza-bicyclo[4,3,0]-5-nonane, and morpholine. Such an alkaline developer solution may contain a water-soluble organic solvent such as ethanol, γ-butyrolactone, dimethylfonrmamide, and N-methyl-2-pyrrolidone as appropriate.

In order to produce a better electrically conductive pattern, the alkaline developer solution may further contain a surface active agent such as nonionic surface active agent so that it accounts for 0.01 to 1 mass %.

The drying methods listed above can also be used for the drying performed after the development step. The drying atmosphere, temperature, and time to use for the drying performed after the development step may be set appropriately depending on the components of the photosensitive resin composition and the thickness of the coating film to be dried, but it is generally preferable to heat it in air in the temperature range of 100° C. to 300° C. for 5 to 120 minutes.

Then, the resulting pattern is cured by heating. An electrically conductive pattern can be produced by curing it in air in the temperature range of 150° C. to 300° C. for 10 to 120 minutes. The curing temperature is more preferably 200° C. to 250° C. and the curing time is more preferably 30 to 90 minutes. If they are in these ranges, a high electrical conductivity can be realized because the electrically conductive particles undergo fusion bonding to a sufficient degree while preventing heat decomposition of the resin component and maintaining good contact between the electrically conductive pattern and the substrate.

In the electrically conductive pattern produced from the photosensitive resin composition according to the present invention, nitrogen atoms preferably account for 0.01 to 1.0 part by mass. If their quantity is 0.01 part by mass or more, good contact can be maintained between the electrically conductive pattern and the substrate, whereas if it is 1.0 part by mass or less, a high electrical conductivity can be realized.

The electrically conductive pattern produced from the photosensitive resin composition according to the present invention preferably has a specific resistance of 2 to 10 μΩ·cm at 25° C. The photosensitive resin composition according to the present invention can be produced by including electrically conductive particles (A) having carbon-containing coat layers, an alkali-soluble resin (B), a photosensitizing agent (C), and a nitrogen-containing compound (d) having a boiling point of 100° C. to 250° C. under atmospheric pressure, and the inclusion of these components serves to produce an electrically conductive pattern with a high electrical conductivity.

If a mesh-like electrically conductive pattern is formed on a substrate, it can serve as transparent electrically conductive wiring to be used in display panels such as touch panels, liquid crystal panels, antenna elements, and organic EL panels, or in wearable terminal devices. A substrate on which an electrically conductive pattern to be formed preferably has a loss tangent of 0.0001 to 0.1 in the frequency range of 2 to 30 GHz in order to work as an antenna element that can receive high frequency radio waves.

A good production method for an image display device according to the present invention includes a step for attaching a substrate having an electrically conductive pattern produced by the production method for an electrically conductive pattern according to the present invention to an image displaying member. Such a substrate having an electrically conductive pattern and an image displaying member can be stuck together with a film having an adhesive material or an adhesive layer interposed between them.

A good production method for a touch panel according to the present invention includes a step for attaching a substrate having an electrically conductive pattern produced by the production method for an electrically conductive pattern according to the present invention to a circuit board. Such a substrate having an electrically conductive pattern and a circuit board can be stuck together with a film having an adhesive material or an adhesive layer interposed between them. A touch sensor can be used as the circuit board.

### EXAMPLES

Described below are examples of the present invention. First, the materials used in the examples and comparative examples are described.

(Electrically Conductive Particles (A) Having Carbon-Containing Coat Layers)

(A-1) silver particles having carbon-containing surface coat layers with an average thickness of 1 nm and having a primary particle diameter of 50 nm (manufactured by Nisshin Engineering Inc.)

(A-2) silver particles having carbon-containing surface coat layers with an average thickness of 1 nm and having a primary particle diameter of 70 nm (manufactured by Nisshin Engineering Inc.)

(A-3) silver particles having carbon-containing surface coat layers with an average thickness of 3 nm and having a primary particle diameter of 40 nm (manufactured by Nisshin Engineering Inc.)

(Alkali-Soluble Resin (B))

(B-1)

In a 500 ml flask, 2.0 g of azobisisobutyronitrile (hereinafter AIBN) and 50 g of propylene glycol monomethyl ether acetate (hereinafter PGMEA) were fed. Then, 38.7 g of methacrylic acid, 79.3 g of benzyl methacrylate, and 22.0 g of tricyclo[5.2.1.0(2,6)]decane-8-yl methacrylate were fed and stirred for a while at room temperature, followed by bubbling to fill the flask with nitrogen and stirring while heating at 70° C. for 5 hours. Subsequently, 21.3 g of glycidyl methacrylate, 1 g of dimethylbenzyl amine, 0.2 g of p-methoxyphenol, and 100 g of PGMEA were added to the resulting solution, followed by stirring while heating at 90° C. for 4 hours and cooling to room temperature. PGMEA was added to the resulting acrylic polymer solution so that the solid content reached 40 mass % to prepare a solution of the alkali-soluble resin (B-1). It had a polystyrene based weight average molecular weight Mw of 18,000 as determined by the GPC method.

(B-2)

First, 1.5 g ofAIBN and 50 g of PGMEAwere fed to a 500 ml flask. Then, 38.7 g of methacrylic acid, 46.9 g of styrene, and 22.0 g of tricyclo[5.2.1.0(2,6)]decane-8-yl methacrylate were fed and stirred for a while at room temperature, followed by bubbling to fill the flask with nitrogen and stirring while heating at 70° C. for 5 hours. Subsequently, 21.3 g of glycidyl methacrylate, 1 g of dimethylbenzyl amine, 0.2 g of p-methoxyphenol, and 100 g of PGMEA were added to the resulting solution, followed by stirring while heating at 90° C. for 4 hours. PGMEA was added to the resulting acrylic polymer solution so that the solid content reached 40 mass % to prepare a solution of the binder resin (B-2). It had a polystyrene based weight average molecular weight Mw of 14,000 as determined by the GPC method.

(Photosensitizing Agent (C))

NCI-831 (registered trademark) (oxime ester based compound; manufactured by Adeka Corporation)

N-1919 (registered trademark) (oxime ester based compound; manufactured by Adeka Corporation)

(Solvent (D))

PGMEA: propylene glycol monomethyl ether acetate (manufactured by Sankyo Chemical Co., Ltd.)

DPM: dipropylene glycol monomethyl ether (manufactured by Toho Chemical Industry Co., Ltd.)

DAA: diacetone alcohol (manufactured by Mitsubishi Chemical Corporation)

EL: ethyl lactate (manufactured by FUJIFILM Wako Pure Chemical Corporation)

GBL: ybutyrolactone (manufactured by FUJIFILM Wako Pure Chemical Corporation)

(Nitrogen-Containing Compound (d))

(Amide Based Solvent (d1))

DMIB: dimethylisobutyl amide (manufactured by Mitsubishi Gas Chemical Co., Inc., a compound as represented by the general formula (1), boiling point 179° C.)

MDMPA: 3-methoxy-N,N-dimethylpropane amide (manufactured by KJ Chemicals Corporation, a compound as represented by the general formula (1), boiling point 215° C.)

DMAc: dimethyl acetamide (manufactured by FUJIFILM Wako Pure Chemical Corporation) (boiling point 165° C.)

NMP: N-methylpyrrolidone (manufactured by FUJIFILM Wako Pure Chemical Corporation) (boiling point 202° C.)

(Dispersing agent (E1) having a tertiary amine and/or quaternary ammonium salt structure) DISPERBYK (registered trademark) 21116 (manufactured by BYK-Chemie Japan)

(Silver Resinate Compound (E2))

Silver neodecanoate (manufactured by FUJIFILM Wako Pure Chemical Corporation)

(Aliphatic Carboxylic Acid (E3))

(E3-1) Neodecanoic acid (manufactured by FUJIFILM Wako Pure Chemical Corporation)

(E3-2) Ethylhexanoic acid (manufactured by FUJIFILM Wako Pure Chemical Corporation)

(E3-3) 2-ethylbutyric acid (manufactured by Tokyo Chemical Industry Co., Ltd.)

(Black Compound (F))

MA100 (carbon black, manufactured by Mitsubishi Chemical Corporation)

(Other Components)

Acrylic monomer: Light Acrylate (registered trademark) PE-3A (manufactured by Kyoeisha Chemical Co., Ltd.)

Silane coupling agent: KBM-503 (manufactured by Shin-Etsu Chemical Co., Ltd.)

Metal chelate compound: ALCH-TR (manufactured by Kawaken Fine Chemicals Co., Ltd.)

(Substrate)

(S-1) Glass substrate with SiO₂-sputtered surface (TU060; manufactured by TOKEN)

(S-2) Glass substrate coated with organic film (acrylic resin)

First, 1 g of AIBN and 50 g of PGMEA were fed to a 500 ml flask. Then, 38.6 g of methacrylic acid, 16.4 g of methyl methacrylate, and 16.4 g of styrene were fed and stirred for a while at room temperature, followed by bubbling to fill the flask with nitrogen and stirring while heating at 70° C. for 5 hours. Subsequently, 28.6 g of glycidyl methacrylate, 1 g of dimethylbenzyl amine, 0.2 g of p-methoxyphenol, and 100 g of PGMEA were added to the resulting solution, followed by stirring while heating at 90° C. for 4 hours and cooling to room temperature. PGMEA was added to the resulting solution so that the solid content reached 40 mass % to prepare a solution of an acrylic polymer. The resulting acrylic polymer had a weight average molecular weight (Mw) of 29,000.

Under yellow light, 0.25 g of OXE-02 (manufactured by BASF), 0.50 g of LA-87 (manufactured by Adeka Corporation), and 0.50 g of a 10 mass % PGMEA solution of t-butyl pyrocatechol (manufactured by Wako Pure Chemical Industries, Ltd.) were dissolved in 14.19 g of PGMEA and 30.00 g of DAA, and then 0.30 g (corresponding to a concentration of 300 ppm) of a 10 mass % PGMEA solution of BYK-333 (manufactured by BYK-Chemie Japan) was added and stirred. To this solution, 6.49 g of a 50 mass % PGMEA solution of TEPIC-VL (manufactured by Nissan Chemical Industries, Ltd), 12.49 g of a 20 mass % PGMEA solution of EG-200 (manufactured by Osaka Gas Chemicals Co., Ltd.), 6.19 g of DPHA (manufactured by Nippon Kayaku Co., Ltd.), 9.36 g of the acrylic polymer solution obtained above, 18.73 g of V-259ME (trade name) (manufactured by Nippon Steel & Sumikin Chemical Co., Ltd.), and 1.00 g of KBM-403 (manufactured by Shin-Etsu Chemical Co., Ltd.) were added and stirred. Subsequently, filtration was performed using a 0.45 μm filter to provide a composition (X-1).

A non-alkali glass substrate (OA-10G; manufactured by Nippon Electric Glass Co., Ltd.) was spin-coated with the composition (X-1) using a spin coater (1H-360S (trade name), manufactured by Mikasa Co., Ltd.) under the conditions of 650 rpm for 5 seconds, and then the substrate was prebaked on a hot plate (SCW-636 (trade name), manufactured by Dainippon Screen Mfg. Co., Ltd.) at 100° C. for 2 minutes to prepare a prebaked film with a film thickness of 2.5 μm. The prebaked film was exposed to light through an appropriate mask using a parallel light mask aligner (PLA-501F (trade name), manufactured by Canon Inc.) equipped with an ultrahigh pressure mercury lamp as light source. Following this, using an automatic development apparatus (AD-2000 (trade name), manufactured by Takizawa Sangyo Co., Ltd.), shower development was performed for 60 seconds with a 0.045 mass % aqueous potassium hydroxide solution and then rinsing was performed for 30 seconds with water to carry out pattern processing. Subsequently, postbaking was performed using an oven (IHPS-222; manufactured by Espec Corp.) at 230° C. for 30 minutes (in air) to prepare a glass substrate coated with the organic film (S-2) (acrylic resin).

(S-3) Glass Substrate Coated with Organic Film (Polyimide Resin)

In a dry nitrogen flow, 29.3 g (0.08 mole) of 2,2-bis(3-amino-4-hydroxyphenyl) hexafluoropropane (BAHF; manufactured by Central Glass Co., Ltd.), 1.24 g (0.005 mole) of 1,3-bis(3-aminopropyl)tetramethyl disiloxane, and 3.27 g (0.03 mole) of 3-aminophenol used as chain end capping agent were dissolved in 150 g of N-methyl-2-pyrrolidone (NMP). To the resulting solution, 31.0 g (0.1 mole) of 3,3′,4,4′-diphenyl ether tetracarboxylic dianhydride (ODPA; manufactured by Manac Incorporated), along with 50 g of NMP, was added and stirred together at 20° C. for 1 hour, followed by stirring at 50° C. for 4 hours. Subsequently, 15 g of xylene was added and stirred at 150° C. for 5 hours while distilling water together with xylene. After the end of the stirring step, the solution was poured into 3 L of water and the resulting white precipitate was collected. This precipitate was collected by filteration, rinsed with water three times, and dried in a vacuum dryer at 80° C. for 24 hours to provide a polyimide polymer. Then, 42.5 g of GBL was added to 7.5 g of this polyimide polymer and stirred. In this way, a composition (X-2) having a solid content of 15 mass % was prepared.

From the composition (X-2), a prebaked film was produced by the same procedure as that used for the organic film (S-2) (acrylic resin). Subsequently, postbaking was performed in an oven at 230° C. for 30 minutes (in air) to prepare a glass substrate coated with an organic film (S-3) (polyimide resin).

(Evaluation for Pattern Processability)

Each of the substrates (S-1) to (S-3) was spin-coated with the composition using a spin coater under the conditions of 300 rpm for 10 seconds or 500 rpm for 1 second, and then the substrate was prebaked on a hot plate at 90° C. for 5 minutes to prepare a prebaked film with a film thickness of 1 μm. The prebaked film was exposed to 300 mJ/cm² of light with a wavelength of 365 nm through a photomask using a parallel light mask aligner equipped with an ultrahigh pressure mercury lamp as light source. The photomask used was a light shielding mask having 30 μm, 10 μm, 6 μm, 4 μm, and 2 μm line-and-space type openings. Following this, using an automatic development apparatus (AD-1200 (trade name), manufactured by Takizawa Sangyo Co., Ltd.), shower development with a 0.08 mass % aqueous TMAH solution was performed for 40 seconds and then rinsing with water was performed for 30 seconds to carry out pattern processing. Additional heating was performed at 230° C. for 60 minutes to form a pattern film of about 0.5 μm. The line pattern of the resulting pattern film was observed and the minimum line width of the remaining pattern was measured to represent the resolution (L/S). The evaluation criteria were set up as follows, resolution: A resolution: ≤2 μm
B 2 μm<resolution≤6 μm
C 6 μm<resolution

(Evaluation for Electrical Conductivity)

Each of the substrates (S-1) to (S-3) was spin-coated with the composition using a spin coater under the conditions of 300 rpm for 10 seconds or 500 rpm for 1 second, and then the substrate was prebaked on a hot plate at 90° C. for 5 minutes to form a prebaked film with a film thickness of 1 μm. The prebaked film was exposed to 300 mJ/cm² of light with a wavelength of 365 nm through a photomask using a parallel light mask aligner equipped with an ultrahigh pressure mercury lamp as light source. The photomask used was a light shielding mask having a linear type opening with a width of 30 μm and a length of 1 cm. Following this, using an automatic development apparatus (AD-1200 (trade name), manufactured by Takizawa Sangyo Co., Ltd.), shower development with a 0.08 mass % aqueous TMAH solution was performed for 40 seconds and then rinsing with water was performed for 30 seconds to carry out pattern processing. Subsequently, postbaking was performed in an oven at 230° C. for 60 minutes (in air) to prepare a line pattern to be used for volume resistivity evaluation.

The resulting line pattern for volume resistivity evaluation was examined by a surface resistance measuring machine (Loresta (registered trademark) -FP; manufactured by Mitsubishi Yuka Kabushiki Kaisha) to determine the surface resistance ρs (Ω/□) and by a surface roughness/contour form measuring machine (SURFCOM (registered trademark) 1400D, manufactured by Tokyo Seimitsu Co., Ltd.) to determine the thickness t (cm), and the two measured values were multiplied together to calculate the volume resistivity (μΩ·cm). The evaluation criteria were set up as follows.

Volume resistivity: S volume resistivity≤7 μΩ·cm
A 7 μΩ·cm<volume resistivity≤10 μΩ·cm
B 10 μΩ·cm<volume resistivity≤30 μΩ·cm
C 30 μΩ·cm<volume resistivity≤50 μΩ·cm
D 50 μΩ·cm<volume resistivity

(Evaluation for Residues on Substrate)

For the substrate carrying a pattern for volume resistivity evaluation formed from the composition, the unexposed portion was subjected to reflectance measurement in order to perform evaluation for residues left on the substrate. Specifically, the total light reflectance (wavelength range 400 to 800 nm) of the unexposed portion was measured before and after film formation using a microspectrometer (LCF-100MA SF, manufactured by Otsuka Electronics Co., Ltd.). Then the change in reflectance was calculated by the equation R−R⁰, wherein R⁰ is the reflectance before film formation and R is the reflectance after film formation. The evaluation criteria were set up as follows.

Reflectance change: A reflectance change≤0.02%
B 0.02%<reflectance change≤0.05%
C 0.05%<reflectance change≤0.08%
D 0.08%<reflectance change

### Example 1

In a homogenizer, 29.20 g of the electrically conductive particles (A-1), 2.92 g of DISPERBYK21116 (manufactured by BYK-Chemie Japan), 34.07 g of NMP, and 34.07 g of DPM were mixed at 1,200 rpm for 30 minutes, followed by dispersing them by a high pressure wet type medialess atomizing device (Nanomizer, manufactured by Nanomizer Inc.) to prepare a silver particles dispersion liquid. The resulting silver particles dispersion liquid had a solid content of 30.00 mass %. To 50.13 g of this dispersion liquid, 6.66 g of a 40 mass % PGMEA solution of the alkali-soluble resin (B-1), 0.24 g of NCI-831, 1.20 g of PE-3A, 0.80 g of KBM-503, 0.06 g of ALCH-TR, 1046 g of NMP, 10.46 g of DPM, and 20.01 g of PGMEA were added and stirred to prepare a photosensitive resin composition 1. Results of evaluation for pattern processability, electrical conductivity, and residues on the substrate are shown in Table 1.

### Example 2

Except for using DMAc instead of the NMP used in Example 1, the same procedure as in Example 1 was carried out to prepare a photosensitive resin composition 2. Results of evaluation for pattern processability, electrical conductivity, and residues on the substrate are shown in Table 1.

### Example 3

Except for using MDMPA instead of the NMP used in Example 1, the same procedure as in Example 1 was carried out to prepare a photosensitive resin composition 3. Results of evaluation for pattern processability, electrical conductivity, and residues on the substrate are shown in Table 1.

### Example 4

Except for using DMIB instead of the NMP used in Example 1, the same procedure as in Example 1 was carried out to prepare a photosensitive resin composition 4. Results of evaluation for pattern processability, electrical conductivity, and residues on the substrate are shown in Table 1.

### Example 5

In a homogenizer, 29.20 g of the electrically conductive particles (A-1), 2.92 g of DISPERBYK21116, 13.63 g of DMIB, and 54.51 g of DPM were mixed at 1,200 rpm for 30 minutes, followed by dispersing them by a high pressure wet type medialess atomizing device (Nanomizer, manufactured by Nanomizer Inc.) to prepare a silver particles dispersion liquid. The resulting silver particles dispersion liquid had a solid content of 30%. To 50.13 g of this dispersion liquid, 6.66 g of a 40% PGMEA solution of the alkali-soluble resin (B-1), 0.24 g of NCI-831, 1.20 g of PE-3A, 0.80 g of KBM-503, 0.06 g of ALCH-TR, 0.98 g of DMIB, 1993 g of DPM, and 20.01 g of PGMEA were added and stirred to prepare a photosensitive resin composition 5. Results of evaluation for pattern processability, electrical conductivity, and residues on the substrate are shown in Table 2.

### Example 6

Except for using 54.51 g of DMIB and 13.63 g of DPM instead of 13.63 g of DMIB and 54.51 g of DPM when preparing a silver particles dispersion liquid and using 19.93 g of DMIB and 0.98 g of DPM instead of 0.98 g of DMIB and 19.93 g of DPM when preparing a resin composition, the same procedure as in Example 5 was carried out to provide a photosensitive resin composition 6. Results of evaluation for pattern processability, electrical conductivity, and residues on the substrate are shown in Table 2.

### Example 7

In a homogenizer, 29.20 g of the electrically conductive particles (A-1), 0.88 g of silver neodecanoate, 35.09 g of DMIB, and 35.09 g of DPM were mixed at 1,200 rpm for 30 minutes, followed by dispersing them by a high pressure wet type medialess atomizing device (Nanomizer, manufactured by Nanomizer Inc.) to prepare a silver particles dispersion liquid. The resulting silver particles dispersion liquid had a solid content of 30%. To 50.13 g of this dispersion liquid, 6.66 g of a 40% PGMEA solution of the alkali-soluble resin (B-1), 0.24 g of NCI-831, 1.20 g of PE-3A, 0.80 g of KBM-503, 0.06 g of ALCH-TR, 10.46 g of DMIB, 10.46 g of DPM, and 20.01 g of PGMEA were added and stirred to prepare a photosensitive resin composition 7. Results of evaluation for pattern processability, electrical conductivity, and residues on the substrate are shown in Table 2.

### Example 8

In a homogenizer, 29.20 g of the electrically conductive particles (A-1), 1.40 g of MA100, 3.06 g of DISPERBYK21116, 35.70 g of DMIB, and 35.70 g of DPM were mixed at 1,200 rpm for 30 minutes, followed by dispersing them by a high pressure wet type medialess atomizing device (Nanomizer, manufactured by Nanomizer Inc.) to prepare a silver particles dispersion liquid. The resulting silver particles dispersion liquid had a solid content of 30%. To 52.53 g of this dispersion liquid, 4.85 g of a 40% PGMEA solution of the alkali-soluble resin (B-1), 0.24 g of NCI-831, 1.20 g of PE-3A, 0.80 g of KBM-503, 0.06 g of ALCH-TR, 9.62 g of DMIB, 9.62 g of DPM, and 21.09 g of PGMEA were added and stirred to prepare a photosensitive resin composition 8. Results of evaluation for pattern processability, electrical conductivity, and residues on the substrate are shown in Table 2.

### Example 9

In a homogenizer, 29.20 g of the electrically conductive particles (A-1), 1.40 g of MA100, 0.92 g of a silver resinate, 36.77 g of DMIB, and 36.77 g of DPM were mixed at 1,200 rpm for 30 minutes, followed by dispersing them by a high pressure wet type medialess atomizing device (Nanomizer, manufactured by Nanomizer Inc.) to prepare a silver particles dispersion liquid. The resulting silver particles dispersion liquid had a solid content of 30%. To 52.53 g of this dispersion liquid, 4.85 g of a 40% PGMEA solution of the alkali-soluble resin (B-1), 0.24 g of NCI-831, 1.20 g of PE-3A, 0.30 g of KBM-503, 0.06 g of ALCH-TR, 9.62 g of DMIB, 9.62 g of DPM, and 21.09 g of PGMEA were added and stirred to prepare a photosensitive resin composition 9. Results of evaluation for pattern processability, electrical conductivity, and residues on the substrate are shown in Table 2.

### Example 10

In a homogenizer, 29.20 g of the electrically conductive particles (A-1), 0.88 g of the aliphatic carboxylic acid (E3-1), 35.09 g of DMIB, and 35.09 g of DPM were mixed at 1,200 rpm for 30 minutes, followed by dispersing them by a high pressure wet type medialess atomizing device (Nanomizer, manufactured by Nanomizer Inc.) to prepare a silver particles dispersion liquid. The resulting silver particles dispersion liquid had a solid content of 30%. To 50.13 g of this dispersion liquid, 6.66 g of a 40% PGMEA solution of the alkali-soluble resin (B-1), 0.24 g of NCI-831, 1.20 g of PE-3A, 0.80 g of KBM-503, 0.06 g of ALCH-TR, 10.46 g of DMIB, 10.46 g of DPM, and 20.01 g of PGMEA were added and stirred to prepare a photosensitive resin composition 10. Results of evaluation for pattern processability, electrical conductivity, and residues on the substrate are shown in Table 3.

### Example 11

In a homogenizer, 29.20 g of the electrically conductive particles (A-1), 0.40 g of the aliphatic carboxylic acid (E3-1), 34.53 g of DMIB, and 34.53 g of DPM were mixed at 1,200 rpm for 30 minutes, followed by dispersing them by a high pressure wet type medialess atomizing device (Nanomizer, manufactured by Nanomizer Inc.) to prepare a silver particles dispersion liquid. The resulting silver particles dispersion liquid had a solid content of 30%. To 49.33 g of this dispersion liquid, 7.25 g of a 40% PGMEA solution of the alkali-soluble resin (B-1), 0.24 g of NCI-831, 1.20 g of PE-3A, 0.80 g of KBM-503, 0.06 g of ALCH-TR, 10.73 g of DMIB, 10.73 g of DPM, and 19.65 g of PGMEA were added and stirred to prepare a photosensitive resin composition 11. Results of evaluation for pattern processability, electrical conductivity, and residues on the substrate are shown in Table 3.

### Example 12

In a homogenizer, 29.20 g of the electrically conductive particles (A-1), 4.00 g of the aliphatic carboxylic acid (E3-1), 38.73 g of DMIB, and 38.73 g of DPM were mixed at 1,200 rpm for 30 minutes, followed by dispersing them by a high pressure wet type medialess atomizing device (Nanomizer, manufactured by Nanomizer Inc.) to prepare a silver particles dispersion liquid. The resulting silver particles dispersion liquid had a solid content of 30%. To 55.33 g of this dispersion liquid, 2.75 g of a 40% PGMEA solution of the alkali-soluble resin (B-1), 0.24 g of NCI-831, 1.20 g of PE-3A, 0.80 g of KBM-503, 0.06 g of ALCH-TR, 8.63 g of DMIB, 8.63 g of DPM, and 22.35 g of PGMEA were added and stirred to prepare a photosensitive resin composition 12. Results of evaluation for pattern processability, electrical conductivity, and residues on the substrate are shown in Table 3.

### Example 13

Except for using the aliphatic carboxylic acid (E3-2) instead of (E3-1) adopted in Example 10, the same procedure was carried out to prepare a photosensitive resin composition 13. Results of evaluation for pattern processability, electrical conductivity, and residues on the substrate are shown in Table 3.

### Example 14

Except for using the aliphatic carboxylic acid (E3-3) instead of (E3-1) adopted in Example 10, the same procedure was carried out to prepare a photosensitive resin composition 13. Results of evaluation for pattern processability, electrical conductivity, and residues on the substrate are shown in Table 3.

### Example 15

In a homogenizer, 29.20 g of the electrically conductive particles (A-1), 088 g of the aliphatic carboxylic acid (E3-1), 35.09 g of DMIB, and 35.09 g of DPM were mixed at 1,200 rpm for 30 minutes, followed by dispersing them by a high pressure wet type medialess atomizing device (Nanomizer, manufactured by Nanomizer Inc.) to prepare a silver particles dispersion liquid. The resulting silver particles dispersion liquid had a solid content of 30%. To 50.13 g of this dispersion liquid, 6.56 g of a 40% PGMEA solution of the alkali-soluble resin (B-1), 0.24 g of NCI-831. 1.20 g of PE-3A, 0.80 g of KBM-503, 0.06 g of ALCH-TR, 0.04 g of the silver resinate, 10.46 g of DMIB, 10.46 g of DPM, and 20.07 g of PGMEAwere added and stirred to prepare a photosensitive resin composition 15. Results of evaluation for pattern processability, electrical conductivity, and residues on the substrate are shown in Table 3.

### Example 16

Except for using the electrically conductive particles (A-2) having carbon-containing coat layers instead of (A-1) adopted in Example 10, the same procedure was carried out to prepare a photosensitive resin composition 16. Results of evaluation for pattern processability, electrical conductivity, and residues on the substrate are shown in Table 4.

### Example 17

Except for using the electrically conductive particles (A-3) having carbon-containing coat layers instead of (A-1) adopted in Example 10, the same procedure was carried out to prepare a photosensitive resin composition 17. Results of evaluation for pattern processability, electrical conductivity, and residues on the substrate are shown in Table 4.

### Example 18

Except for using the alkali-soluble resin (B-2) instead of (B-1) adopted in Example 10, the same procedure was carried out to prepare a photosensitive resin composition 18. Results of evaluation for pattern processability, electrical conductivity, and residues on the substrate are shown in Table 4.

### Example 19

Except for using the N-1919 photosensitizing agent instead of NCI-831 adopted in Example 10, the same procedure was carried out to prepare a photosensitive resin composition 19. Results of evaluation for pattern processability, electrical conductivity, and residues on the substrate are shown in Table 4.

### Comparative Example 1

In a homogenizer, 29.20 g of the electrically conductive particles (A-1), 2.92 g of DISPERBYK21116, 34.07 g of PGEMA, and 34.07 g of DPM were mixed at 1,200 rpm for 30 minutes, followed by dispersing them by a high pressure wet type medialess atomizing device (Nanomizer, manufactured by Nanomizer Inc.) to prepare a silver particles dispersion liquid. The resulting silver particles dispersion liquid had a solid content of 30%. To 50.13 g of this dispersion liquid, 6.66 g of a 40% PGMEA solution of the alkali-soluble resin (B-1), 024 g of NCI-831, 1.20 g of PE-3A, 0.80 g of KBM-503, 0.06 g of ALCH-TR, 22.46 g of DPM, and 1846 g of PGMEA were added and stirred to prepare a composition 1 for the comparative example. Results of evaluation for pattern processability, electrical conductivity, and residues on the substrate are shown in Table 5.

### Comparative Example 2

Except for using 34.07 g of DAA instead of 34.07 g of PGMEA when preparing a silver particles dispersion liquid and using 10.46 g of DAA, 10.46 g of DPM, and 20.007 g of PGMEA instead of 22.46 g of DPM and 18.46 g of PGMEA as solvent components that are added when preparing a photosensitive resin composition, the same procedure as in Comparative example 1 was carried out to produce a composition 2 for the comparative example. Results of evaluation for pattern processability, electrical conductivity, and residues on the substrate are shown in Table 5.

### Comparative Example 3

Except for using 34.07 g of EL instead of 34.07 g of DAA when preparing a silver particles dispersion liquid and using 10.46 g of EL instead of 10.46 g of DAA as solvent components that were added when preparing a photosensitive resin composition, the same procedure as in Comparative example 2 was carried out to produce a composition 3 for the comparative example. Results of evaluation for pattern processability, electrical conductivity, and residues on the substrate are shown in Table 5.

### Comparative Example 4

Except for using 34.07 g of GBL instead of 34.07 g of DAA when preparing a silver particles dispersion liquid and using 10.46 g of GBL instead of 10.46 g of DAA as solvent components that were added when preparing a photosensitive resin composition, the same procedure as in Comparative example 2 was carried out to produce a composition 4 for the comparative example. Results of evaluation for pattern processability, electrical conductivity, and residues on the substrate are shown in Table 5.

TABLE 1

| | | | Example 1 | Example 2 | Example 3 | Example 4 |
|---|---|---|---|---|---|---|
| | | | photosensitive | photosensitive | photosensitive | photosensitive |
| | | | resin | resin | resin | resin |
| Resin composition | | | composition 1 | composition 2 | composition 3 | composition 4 |
| Components | electrically conductive particles (A) having carbon-containing coat | | (A-1) | (A-1) | (A-1) | (A-1) |
| | layers | | | | | |
| | alkali-soluble resin (B) | | (B-1) | (B-1) | (B-1) | (B-1) |
| | photosensitizer (C) | | NCI-831 | NCI-831 | NCI-831 | NCI-831 |
| | nitrogen-containing | name | NMP | DMAc | MDMPA | DMIB |
| | compound (d) | type | amide | amide | amide | amide |
| | | | based | based | based | based |
| | | | solvent | solvent | solvent | solvent |
| | | | (d1) | (d1) | (d1) | (d1) |
| | | boiling point of amide based solvent (d1) | 202° C. | 165° C. | 215° C. | 179° C. |
| | | content of amide based solvent (d1) *1 | 35 | 35 | 35 | 35 |
| | other solvent | | DPM | DPM | DPM | DPM |
| | | | PGMEA | PGMEA | PGMEA | PGMEA |
| | dispersing agent (E1) having tertiary amine and/or quaternary | | BYK-21116 | BYK-21116 | BYK-21116 | BYK-21116 |
| | ammonium salt structure | | | | | |
| | other component | | PE-3A | PE-3A | PE-3A | PE-3A |
| | | | KBM-503 | KBM-503 | KBM-503 | KBM-503 |
| | | | ALCH-TR | ALCH-TR | ALCH-TR | ALCH-TR |
| Evaluation | pattern processability | on (S-1) | B | B | B | B |
| results | resolution L/S | on (S-2) | B | B | A | A |
| | (μm) | on (S-3) | B | B | A | A |
| | electrical conductivity | on (S-1) | B | B | B | B |
| | volume resistivity | on (S-2) | C | C | B | B |
| | (μΩ · cm) | on (S-3) | C | C | B | B |
| | residues on substrate | on (S-1) | B | B | B | B |
| | reflectance change (%) | on (S-2) | B | B | A | A |
| | | on (S-3) | B | B | A | A |

*1: mass % content in total solvent contained in photosensitive resin composition

TABLE 2

| | | | Example 5 | Example 6 | Example 7 | Example 8 | Example 9 |
|---|---|---|---|---|---|---|---|
| | | | photo- | photo- | photo- | photo- | photo- |
| | | | sensitive | sensitive | sensitive | sensitive | sensitive |
| | | | resin | resin | resin | resin | resin |
| | | | compo- | compo- | compo- | compo- | compo- |
| Resin composition | | | sition 5 | sition 6 | sition 7 | sition 8 | sition 9 |
| Components | electrically conductive particles (A) having carbon- | | (A-1) | (A-1) | (A-1) | (A-1) | (A-1) |
| | containing coat layers | | | | | | |
| | alkali-soluble resin (B) | | (B-1) | (B-1) | (B-1) | (B-1) | (B-1) |
| | photosensitizer (C) | | NCI-831 | NCI-831 | NCI-831 | NCI-831 | NCI-831 |
| | nitrogen-containing | name | DMIB | DMIB | DMIB | DMIB | DMIB |
| | compound (d) | type | amide based | amide based | amide based | amide based | amide based |
| | | | solvent (d1) | solvent (d1) | solvent (d1) | solvent (d1) | solvent (d1) |
| | | boiling point of amide based | 179° C. | 179° C. | 179° C. | 179° C. | 179° C. |
| | | solvent (d1) | | | | | |
| | | content of amide based solvent | 10 | 60 | 35 | 35 | 35 |
| | | (d1) *1 | | | | | |
| | other solvent | | DPM | DPM | DPM | DPM | DPM |
| | | | PGMEA | PGMEA | PGMEA | PGMEA | PGMEA |
| | dispersing agent (E1) having tertiary amine and/or | | BYK-21116 | BYK-21116 | — | BYK-21116 | — |
| | quaternary ammonium salt structure | | | | | | |
| | silver resinate compound (E2) | | — | — | silver resinate | — | silver resinate |
| | content of (E2) and (E3) *2 | | 0 | 0 | 2.2% | 0 | 2.2% |
| | black compound (F) | | — | — | — | MA100 | MA100 |
| | other component | | PE-3A | PE-3A | PE-3A | PE-3A | PE-3A |
| | | | KBM-503 | KBM-503 | KBM-503 | KBM-503 | KBM-503 |
| | | | ALCH-TR | ALCH-TR | ALCH-TR | ALCH-TR | ALCH-TR |
| Evaluation | pattern processability | on (S-1) | B | B | B | A | A |
| results | resolution L/S | on (S-2) | A | A | A | A | A |
| | (μm) | on (S-3) | A | A | A | A | A |
| | electrical conductivity | on (S-1) | B | B | S | B | S |
| | volume resistivity | on (S-2) | B | B | A | B | A |
| | (μΩ · cm) | on (S-3) | B | B | A | B | A |
| | residues on substrate | on (S-1) | B | B | B | B | B |
| | reflectance change (%) | on (S-2) | A | A | A | A | A |
| | | on (S-3) | A | A | A | A | A |

*1: mass % content in total solvent contained in photosensitive resin composition
*2: total quantity of silver resinate (E2) and aliphatic carboxylic acid (E3) relative to 100 parts by mass of electrically conductive particles (A)

TABLE 3

| | | | Exam- | Exam- | Exam- | Exam- | Exam- | Exam- |
|---|---|---|---|---|---|---|---|---|
| | | | ple 10 | ple 11 | ple 12 | ple 13 | ple 14 | ple 15 |
| | | | photo- | photo- | photo- | photo- | photo- | photo- |
| | | | sensitive | sensitive | sensitive | sensitive | sensitive | sensitive |
| | | | resin | resin | resin | resin | resin | resin |
| | | | compo- | compo- | compo- | compo- | compo- | compo- |
| Resin composition | | | sition 10 | sition 11 | sition 12 | sition 13 | sition 14 | sition 15 |
| Components | electrically conductive particles (A) having carbon- | | (A-1) | (A-1) | (A-1) | (A-1) | (A-1) | (A-1) |
| | containing coat layers | | | | | | | |
| | alkali-soluble resin (B) | | (B-1) | (B-1) | (B-1) | (B-1) | (B-1) | (B-1) |
| | photosensitizer (C) | | NCI-831 | NCI-831 | NCI-831 | NCI-831 | NCI-831 | NCI-831 |
| | nitrogen-containing | name | DMIB | DMIB | DMIB | DMIB | DMIB | DMIB |
| | compound (d) | type | amide | amide | amide | amide | amide | amide |
| | | | based | based | based | based | based | based |
| | | | solvent | solvent | solvent | solvent | solvent | solvent |
| | | | (d1) | (d1) | (d1) | (d1) | (d1) | (d1) |
| | | boiling point of amide | 179° C. | 179° C. | 179° C. | 179° C. | 179° C. | 179° C. |
| | | based solvent (d1) | | | | | | |
| | | content of amide based | 60 | 35 | 35 | 35 | 35 | 35 |
| | | solvent (d1) *1 | | | | | | |
| | other solvent | | DPM | DPM | DPM | DPM | DPM | DPM |
| | | | PGMEA | PGMEA | PGMEA | PGMEA | PGMEA | PGMEA |
| | dispersing agent (E1) having tertiary amine and/or | | — | — | — | — | — | — |
| | quaternary ammonium salt structure | | | | | | | |
| | silver resinate compound (E2) | | — | — | — | — | — | silver |
| | | | | | | | | resinate |
| | aliphatic carboxylic acid (E3) | | (E3-1) | (E3-1) | (E3-1) | (E3-2) | (E3-3) | (E3-1) |
| | content of (E2) and (E3) *2 | | 2.2% | 1.0% | 10% | 2.2% | 2.2% | 3.2% |
| | black compound (F) | | | | | | | |
| | other component | | PE-3A | PE-3A | PE-3A | PE-3A | PE-3A | PE-3A |
| | | | KBM-503 | KBM-503 | KBM-503 | KBM-503 | KBM-503 | KBM-503 |
| | | | ALCH-TR | ALCH-TR | ALCH-TR | ALCH-TR | ALCH-TR | ALCH-TR |
| Evaluation | pattern processability | on (S-1) | A | A | A | A | A | A |
| results | resolution L/S | on (S-2) | A | A | A | A | A | A |
| | (μm) | on (S-3) | A | A | A | A | A | A |
| | electrical conductivity | on (S-1) | A | A | A | A | A | S |
| | volume resistivity | on (S-2) | B | B | B | B | B | A |
| | (μΩ · cm) | on (S-3) | B | B | B | B | B | A |
| | residues on substrate | on (S-1) | A | A | A | A | A | A |
| | reflectance change (%) | on (S-2) | A | A | A | A | A | A |
| | | on (S-3) | A | A | A | A | A | A |

*1: mass % content in total solvent contained in photosensitive resin composition
*2: total quantity of silver resinate (E2) and aliphatic carboxylic acid (E3) relative to 100 parts by mass of electrically conductive particles (A)

TABLE 4

| | | | Example 16 | Example 17 | Example 18 | Example 19 |
|---|---|---|---|---|---|---|
| | | | photosensitive | photosensitive | photosensitive | photosensitive |
| | | | resin | resin | resin | resin |
| Resin composition | | | composition 16 | composition 17 | composition 18 | composition 19 |
| Components | electrically conductive particles (A) having carbon-containing coat | | (A-2) | (A-3) | (A-1) | (A-1) |
| | layers | | | | | |
| | alkali-soluble resin (B) | | (B-1) | (B-1) | (B-2) | (B-1) |
| | photosensitizer (C) | | NCI-831 | NCI-831 | NCI-831 | N-1919 |
| | nitrogen-containing | name | DMIB | DMIB | DMIB | DMIB |
| | compound (d) | type | amide | amide | amide | amide |
| | | | based | based | based | based |
| | | | solvent | solvent | solvent | solvent |
| | | | (d1) | (d1) | (d1) | (d1) |
| | | boiling point of amide based solvent | 179° C. | 179° C. | 179° C. | 179° C. |
| | | (d1) | | | | |
| | | content of amide based solvent (d1) *1 | 35 | 35 | 35 | 35 |
| | other solvent | | DPM | DPM | DPM | DPM |
| | | | PGMEA | PGMEA | PGMEA | PGMEA |
| | dispersing agent (E1) having tertiary amine and/or quaternary | | — | — | — | — |
| | ammonium salt structure | | | | | |
| | silver resinate compound (E2) | | — | — | — | — |
| | aliphatic carboxylic acid (E3) | | (E3-1) | (E3-1) | (E3-1) | (E3-1) |
| | content of (E2) and (E3) *2 | | 2.2% | 2.2% | 2.2% | 2.2% |
| | black compound (F) | | — | — | — | — |
| | other component | | PE-3A | PE-3A | PE-3A | PE-3A |
| | | | KBM-503 | KBM-503 | KBM-503 | KBM-503 |
| | | | ALCH-TR | ALCH-TR | ALCH-TR | ALCH-TR |
| Evaluation | pattern processability | on (S-1) | A | A | A | A |
| results | resolution L/S | on (S-2) | A | A | A | A |
| | (μm) | on (S-3) | A | A | A | A |
| | electrical conductivity | on (S-1) | A | A | A | A |
| | volume resistivity | on (S-2) | B | B | B | B |
| | (μΩ · cm) | on (S-3) | B | B | B | B |
| | residues on substrate | on (S-1) | A | A | A | A |
| | reflectance change (%) | on (S-2) | A | A | A | A |
| | | on (S-3) | A | A | A | A |

*1: mass % content in total solvent contained in photosensitive resin composition
*2: total quantity of silver resinate (E2) and aliphatic carboxylic acid (E3) relative to 100 parts by mass of electrically conductive particles (A)

TABLE 5

| | | | Comparative | Comparative | Comparative | Comparative |
|---|---|---|---|---|---|---|
| | | | example 1 | example 2 | example 3 | example 4 |
| | | | Composition | Composition | Composition | Composition |
| | | | 1 for | 2 for | 3 for | 4 for |
| | | | comparative | comparative | comparative | comparative |
| Resin composition | | | example | example | example | example |
| Components | electrically conductive particles (A) having carbon-containing coat | | (A-1) | (A-1) | (A-1) | (A-1) |
| | layers | | | | | |
| | alkali-soluble resin (B) | | (B-1) | (B-1) | (B-1) | (B-1) |
| | photosensitizer (C) | | NCI-831 | NCI-831 | NCI-831 | NCI-831 |
| | nitrogen-containing compound (d) | | — | — | — | — |
| | solvent (D) | | — | DAA | EL | GBL |
| | | | DPM | DPM | DPM | DPM |
| | | | PGMEA | PGMEA | PGMEA | PGMEA |
| | dispersing agent (E1) having tertiary amine and/or quatemary | | BYK-21116 | BYK-21116 | BYK-21116 | BYK-21116 |
| | ammonium salt structure | | | | | |
| | | | PE-3A | PE-3A | PE-3A | PE-3A |
| | other component | | KBM-503 | KBM-503 | KBM-503 | KBM-503 |
| | | | ALCH-TR | ALCH-TR | ALCH-TR | ALCH-TR |
| Evaluation | pattern processability | on (S-1) | B | B | B | B |
| results | resolution L/S | on (S-2) | C | C | C | C |
| | (μm) | on (S-3) | C | C | C | C |
| | electrical conductivity | on (S-1) | C | C | C | C |
| | volume resistivity | on (S-2) | D | D | D | D |
| | (μΩ · cm) | on (S-3) | D | D | D | D |
| | residues on substrate | on (S-1) | D | C | D | C |
| | reflectance change (%) | on (S-2) | D | D | D | D |
| | | on (S-3) | D | D | D | D |

A comparison between Examples 1 to 19 and Comparative examples 1 to 4 shows that the inclusion of an amide based solvent serves to reduce residues regardless of the type of the substrate in use.

### INDUSTRIAL APPLICABILITY

The photosensitive resin composition according to the present invention can suitably serve to form electrically conductive patterns to be used in touch panels, displays, image sensors, organic electroluminescence lighting, solar cells, and the like.

1. A photosensitive resin composition comprising electrically conductive particles (A) having carbon-containing coat layers, an alkali-soluble resin (B), a photosensitizing agent (C), and an amide based solvent (d1) having a boiling point of 100° C. to 250° C. under atmospheric pressure, wherein the amide based solvent (d1) includes a compound represented by formula (1) below: 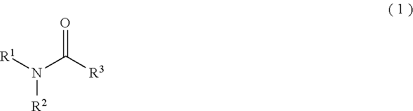
wherein in formula (1),
R¹ and R² are each independently a hydrogen atom or a linear alkyl group having 1 to 3 carbon atoms;
R³ is an organic group having 1 to 4 carbon atoms; and
the total number of carbon atoms present in R¹, R², and R³ is in the range of 4 to 8.

2. (canceled)

3. (canceled)

4. A photosensitive resin composition as set forth in claim 1, wherein a solvent (D) is further included and the amide based solvent (d1) in the solvent (D) accounts for 5 to 65 mass %.

5. A photosensitive resin composition as set forth in claim 1, further comprising a dispersing agent (E1) having a tertiary amine and/or quaternary ammonium salt structure.

6. A photosensitive resin composition as set forth in claim 1, further comprising a silver resinate compound (E2).

7. A photosensitive resin composition as set forth claim 6, wherein the silver resinate compound (E2) contains a silver carboxylate having 1 to 12 carbon atoms.

8. A photosensitive resin composition as set forth in claim 1, further comprising an aliphatic carboxylic acid (E3).

9. A photosensitive resin composition as set forth in claim 8, wherein the silver resinate compound (E2) and the aliphatic carboxylic acid (E3) altogether account for 1 to 10 parts by mass relative to 100 parts by mass of the electrically conductive particles (A).

10. A photosensitive resin composition as set forth in claim 1, further comprising a black compound (F).

11. A photosensitive resin composition as set forth in claim 10, wherein the black compound (F) contains carbon black.

12. A substrate with an electrically conductive pattern comprising a substrate and an electrically conductive pattern formed from a photosensitive resin composition as set forth in claim 1, the electrically conductive pattern containing 0.01 to 1.0 part by mass of nitrogen atoms and the electrically conductive pattern having a specific resistance of 2 to 10 μΩ·cm at 25° C.

13. A substrate with an electrically conductive pattern as set forth in claim 12, wherein the dielectric loss is 0.0001 to 0.1 in the frequency range of 2 to 30 GHz.

14. An antenna element having a substrate with an electrically conductive pattern as set forth in claim 12.

15. A production method for an electrically conductive pattern comprising:
a step for forming on a substrate a dry film of a photosensitive resin composition as set forth in claim 1,
a step for exposing the dry film to light and developing it to form a pattern on the substrate, and
a step for heating the resulting pattern.

16. A production method for an image display device comprising a step for attaching a substrate with an electrically conductive pattern formed by a production method for an electrically conductive pattern as set forth in claim 15 to an image displaying member.

17. A production method for a touch panel comprising a step for attaching a substrate with an electrically conductive pattern formed by a production method for an electrically conductive pattern as set forth in claim 15 to a circuit board.
